(19) United States
(12) Patent Application Publication
(10) Pub. No.: US 2024/0387350 A1
(43) Pub. Date: Nov. 21, 2024

(54) PACKAGE WITH EMBEDDED TRACES

(71) Applicant: PANJIT INTERNATIONAL INC., Kaohsiung City (TW)

(72) Inventors: CHUNG-HSIUNG HO, Kaohsiung City (TW); YUNG-HUI WANG, Kaohsiung City (TW); JENG-SIAN WU, Taoyuan City (TW)

(21) Appl. No.: 18/455,156

(22) Filed: Aug. 24, 2023

(30) Foreign Application Priority Data
May 19, 2023 (TW) 112118703

(51) Int. Cl. H01L 23/50; H01L 21/56; H01L 23/00; H01L 23/31

(52) U.S. Cl. CPC H01L 23/50; H01L 21/561; H01L 21/568; H01L 23/3135; H01L 24/19; H01L 24/20; H01L 2224/19; H01L 2224/2101; H01L 2224/221; H01L 2224/95001

(57) ABSTRACT

A package with embedded traces has a main body and multiple leads. The main body includes an insulating body, a die in the insulating body, and multiple conductive traces in the insulating body, wherein the die is electrically connected to the insulating body. The multiple leads extend outward from the main body. Each of the multiple leads includes a lead carrier and two conducting layers that are formed on opposite surfaces of the lead carrier and electrically connected to the respective conductive trace so that the two conducting layers are electrically connected to the die, wherein at least one of the two conducting layers is embedded in the lead carrier.

### CROSS REFERENCE TO RELATED APPLICATIONS

This non-provisional application claims the benefit under 35 U.S.C. § 119 (a) to patent application No. 112118703 filed in Taiwan on May 19, 2023, which is hereby expressly incorporated by reference into the present application.

### BACKGROUND OF THE INVENTION

### 1. Field of the Invention

The present invention relates to a package, particularly to a package with embedded traces.

### 2. Description of the Related Art

Conventionally, a semiconductor package has multiple leads manufactured based on a lead frame. Taking a transistor 60 shown in FIGS. 10 and 11 as an example, the transistor 60 has a base 61, a lead frame 62, a die 63 and a package body 64. The die 63 is attached on a surface of the base 61. The lead frame 62 has a plurality of leads 620 each being connected to a respective pad 630 on a top surface of the die 63. The package body 64 covers the base 61, the die 63 and the lead frame 62. The plurality of leads 620 protrude from the package body 64.

Different lead frames are designed for various types of semiconductor packages, i.e. a specific type of lead frame 63 cannot be widely used to manufacture all kinds of semiconductor packages. The disadvantage of using the lead frame 62 is that each type of semiconductor package needs to adopt a dedicated lead frame 62. For packaging factories, purchasing various lead frames from suppliers as raw material is necessary, and the manufacturing cost is relatively high. In addition, because the lead frame has a certain thickness, for example the lead frame 62 in FIG. 11 being bent to extend from the top of the die 63 to the bottom of the die 63, the overall thickness of the semiconductor element will be affected due to the thickness of the lead frame 63, which is unfavorable to minimize the size of the package.

### SUMMARY OF THE INVENTION

An objective of the present disclosure is to provide a package with embedded traces without using the lead frame for reducing manufacturing cost and minimizing the size of the package.

The package with embedded traces comprises:
a main body comprising:
   an insulating body; and
   a die and multiple conductive traces mounted in the insulating body, wherein the die is electrically connected to the multiple conductive traces; and
multiple leads extending outward from the main body, and each of the multiple leads comprising:
   a lead carrier integrally extending from the isolation body and having two opposite surfaces; and
   two conducting layers formed on the two opposite surfaces of the lead carrier respectively and electrically connected to one of the multiple conductive traces so that the two conducting layers of each lead is electrically connected to the die, wherein at least one of the two conducting layers of each lead is embedded in the lead carrier.

In comparison to the conventional package, the present invention can manufacture leads of the package through the panel level package process (PLP) instead of using the metal lead frame as raw material. Accordingly, the manufacturer does not need to cut the lead frame twice or to sequentially etch and cut the lead frame. Therefore, a thinner lead frame is applicable to simplify the manufacturing processes, reduce the thickness of the package, and lower the manufacturing costs.

Other objectives, advantages and novel features of the invention will become more apparent from the following detailed description when taken in conjunction with the accompanying drawings.

### BRIEF DESCRIPTION OF THE DRAWINGS

FIG. 1 is a perspective view of a package with embedded traces according to one embodiment of the present invention;

FIG. 2 is a bottom plan view of FIG. 1;

FIG. 3 is a cross sectional view of FIG. 1;

FIG. 4 is a perspective view of the package with embedded traces according to another embodiment of the present invention;

FIGS. 5A to 5K are cross sectional views showing a method of manufacturing the package of the present invention;

FIG. 6 is a perspective view of a semi-finished product according to the method of the present invention;

FIG. 7 is another perspective view of the semi-finished product according to the method of the present invention;

FIG. 8 is plan view showing multiple semi-finished leads according to the method of the present invention;

FIG. 9 shows the semi-finished product being sawed according to the method of the present invention;

FIG. 10 is a perspective view of a conventional semiconductor package; and

FIG. 11 is a perspective view of the conventional semiconductor package.

### DETAILED DESCRIPTION OF THE INVENTION

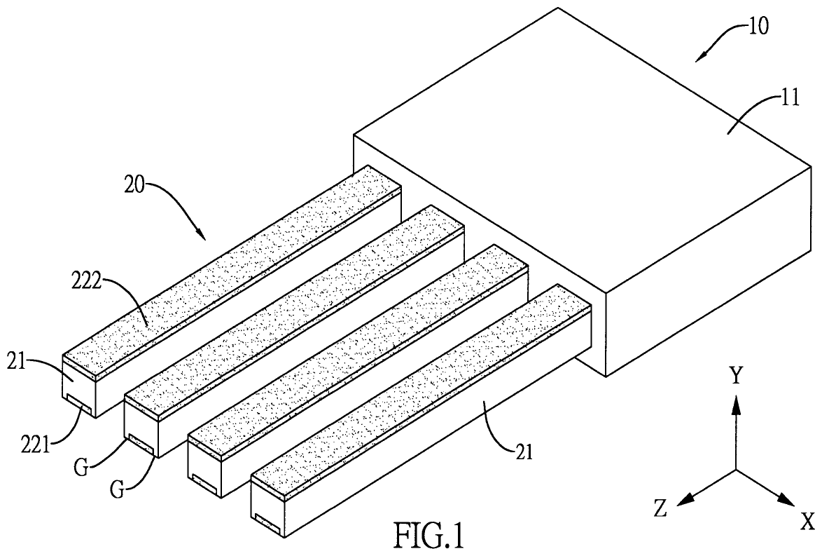

With reference to FIGS. 1, 2, and 3, a package with embedded traces in accordance with one embodiment of the present invention comprises a main body 10 and a plurality of leads 20. In this embodiment, the package is a pin through hole (PTH) type package. The plurality of leads 20 may extend from, but not limited to, a same side of the main body 10. In another embodiment, the plurality of leads 20 may extend from different sides of the main body 10.

The main body 10 includes an insulating body 11, a die 12 and multiple conductive traces 13. The die 12 and the plurality of conductive traces 13 are all mounted in and covered by the insulating body 11. The die 12 has multiple pads respectively and electrically connected to the conductive traces 13 for power or signal transmissions to the die 12. The plurality of conductive traces 13 may be implemented by a redistribution layer (RDL). One end of each conductive trace 13 is connected to a respective pad 120 of the die 12, while the other end of the conductive trace 13 extending to one side of the insulating body 11 is connected to a respective lead 20.

Each lead 20 is composed of a lead carrier 21 and two conducting layers 221, 222. The lead carrier 21 is a pin-shaped insulator extending integrally from one side of the insulating body 11 and has two opposite surfaces, such as a top surface and a bottom surface. The two conducting layers 221, 222 are respectively formed on the two opposite surfaces and electrically connected to the conductive trace 13 so that the two conducting layers 221, 222 of the lead 20 are electrically connected to the pad 120 of the die 12. The two conducting layers 221, 222 may be manufactured to have the same or different trace widths.

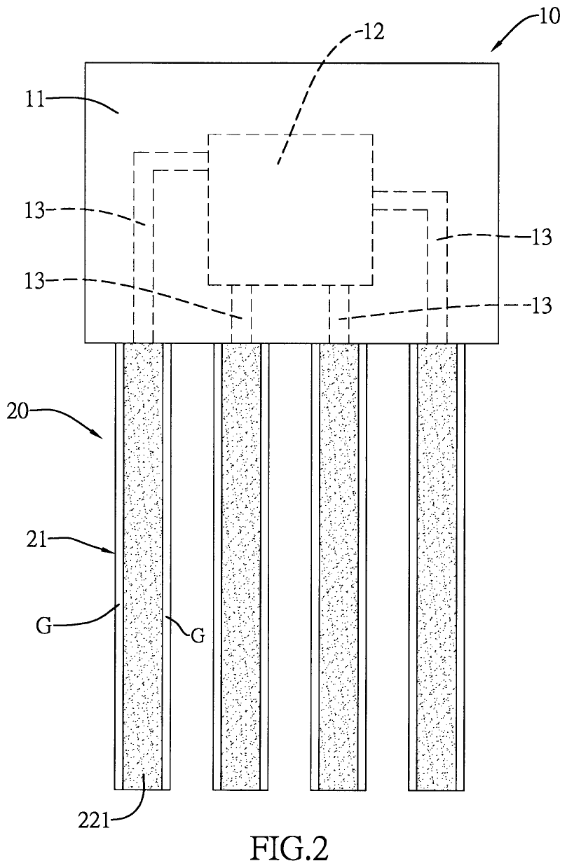

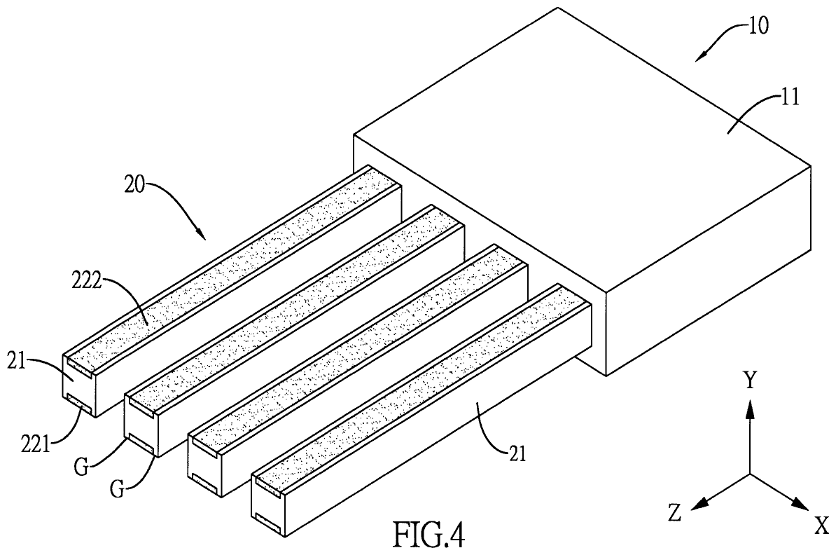

As shown in FIGS. 1 and 2, at least one of the two conducting layers such as the conducting layer 221 is partially embedded into the bottom surface of the lead carrier 21, and the conducting layer 221 has a surface being coplanar with and exposed from the bottom surface of the lead carrier 21. The trace width of the conducting layer 221 is smaller than the width of the lead carrier 21. Two gaps G are respectively formed between two side edges of the conducting layer 221 and two side edges of the lead carrier 21. The other conducting layer 222 is formed on the top surface of the lead carrier 21 and has a trace width equal to the width of the lead carrier 21. The two side edges of the conducting layer 222 respectively align with the two side edges of the lead carrier 21. With further reference to FIG. 4, the two conducting layers 221, 222 in this embodiment are respectively embedded in the top surface and the bottom surface of the lead carrier 21, and the trace width of each conducting layer 221, 222 is smaller than the trace width of the lead carrier 21.

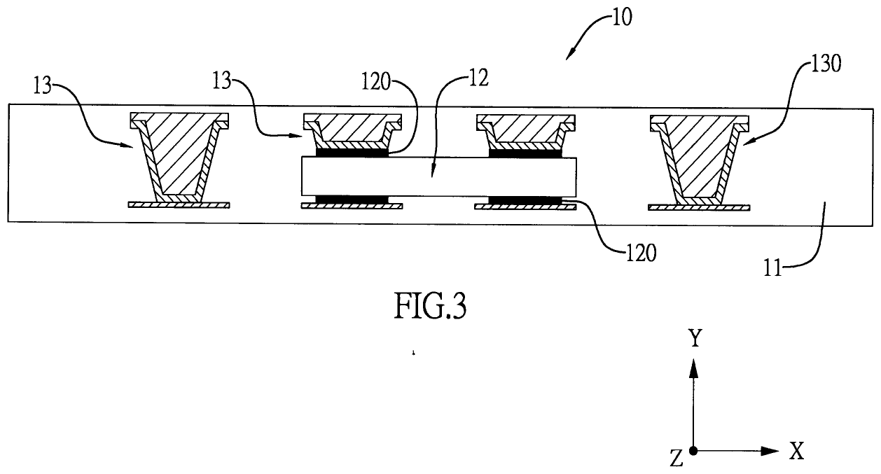

The two conducting layers 221, 222 of each lead 20 are electrically connected to each other. As mentioned above, each conductive trace 13 in the main body 10 may be implemented by RDL. Further referring to FIG. 3, the conductive traces 13 in the insulating body 11 include conductive vias 130. The two conducting layers 221, 222 of each lead 20 extend into the insulating body 11 to respectively and electrically connect to a top and a bottom of a respective conductive via 130 so that the two conducting layers 221, 222 are electrically interconnected through the conductive via 130.

The accompanying drawings are presented to describe examples of the present teachings, and are not limiting. An embodiment of the manufacturing method of the present invention is described as follows. The manufacturing method of the present invention can manufacture leads 20 of the package through the panel level package (PLP) process instead of using the metal lead frame as raw material.

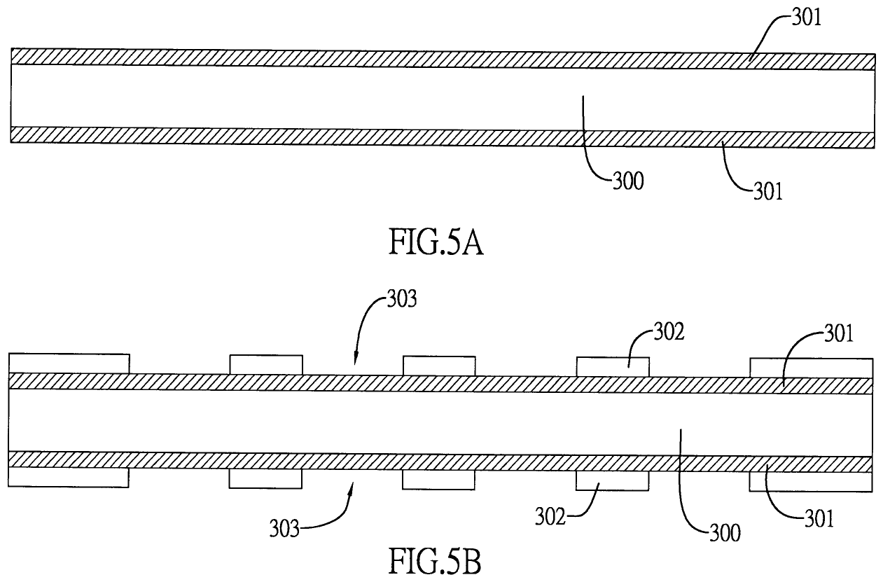

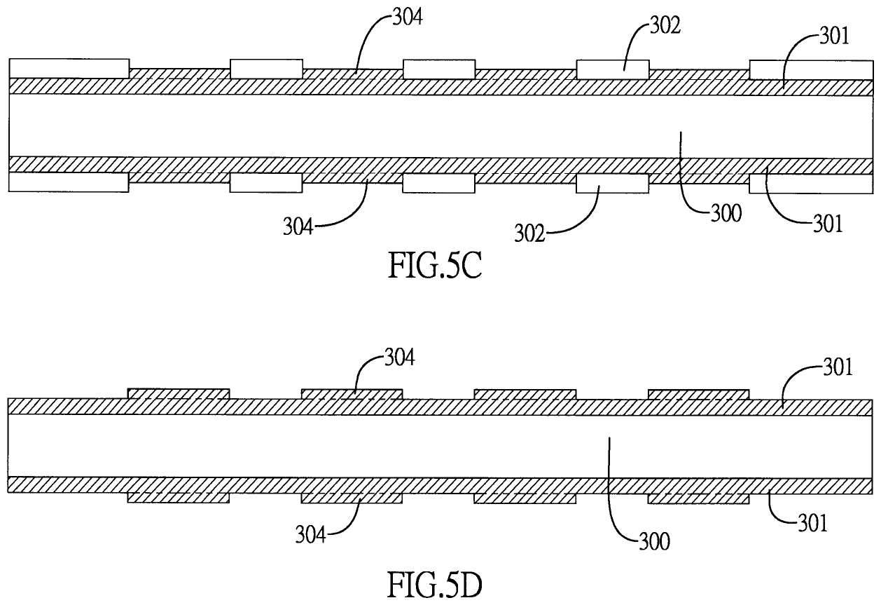

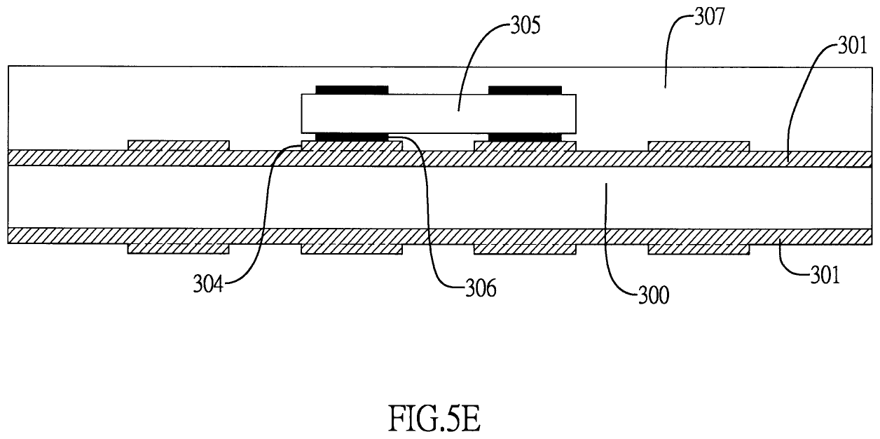

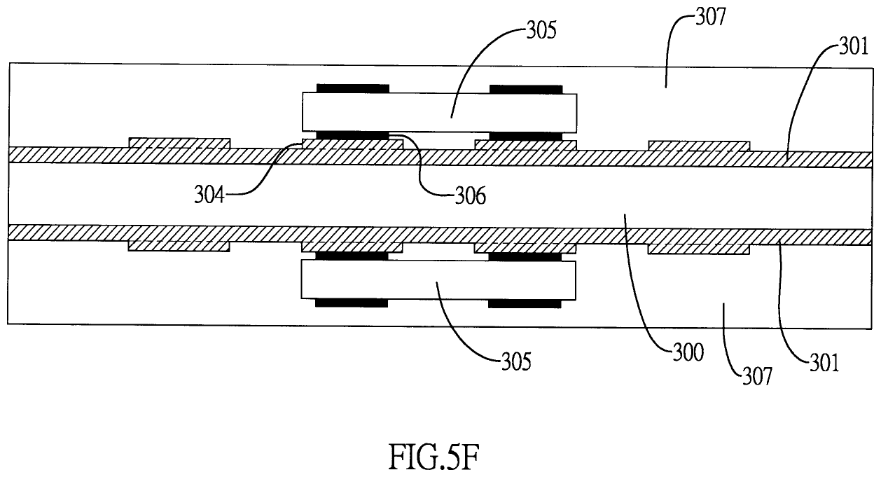

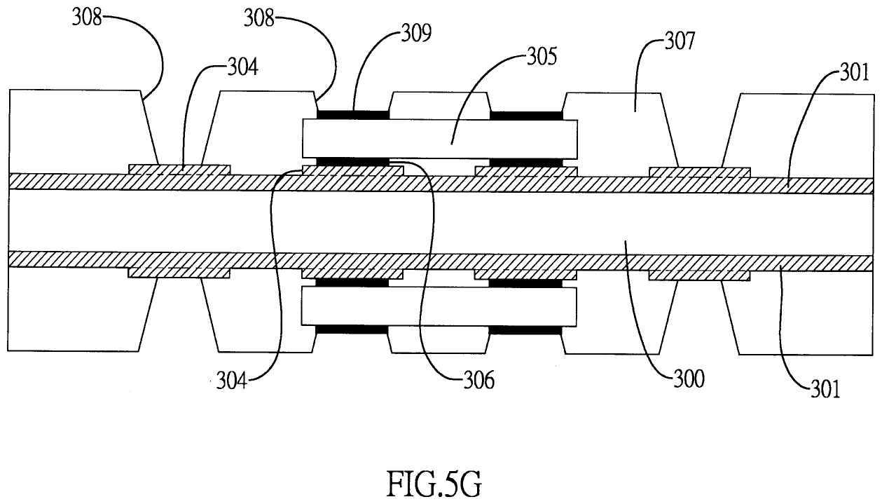

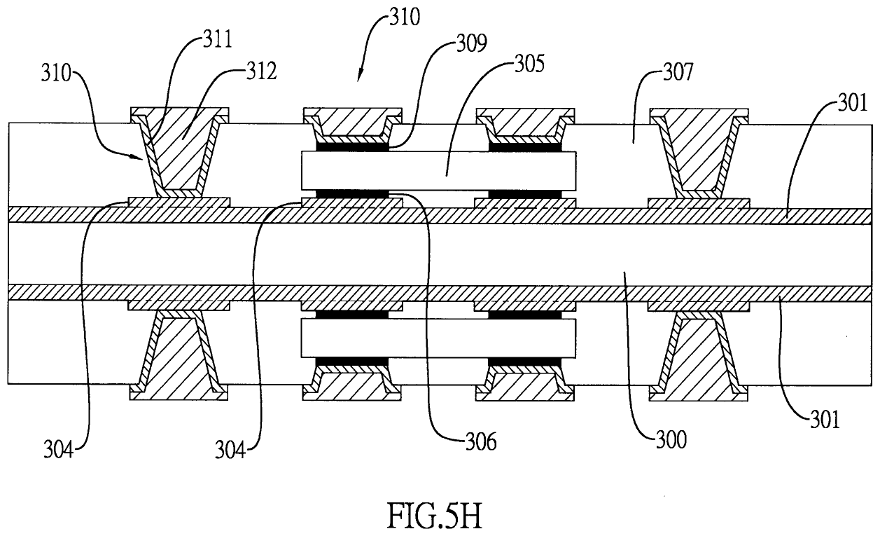

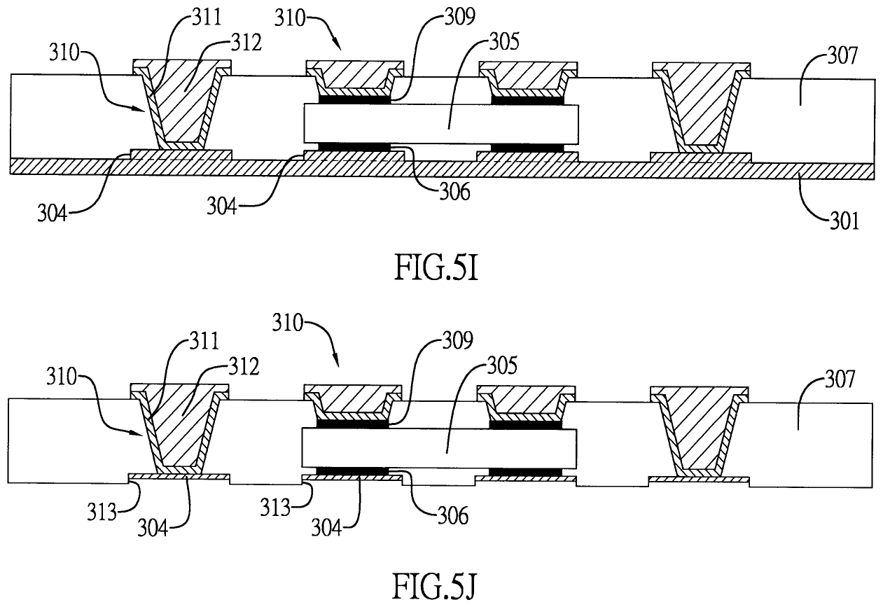

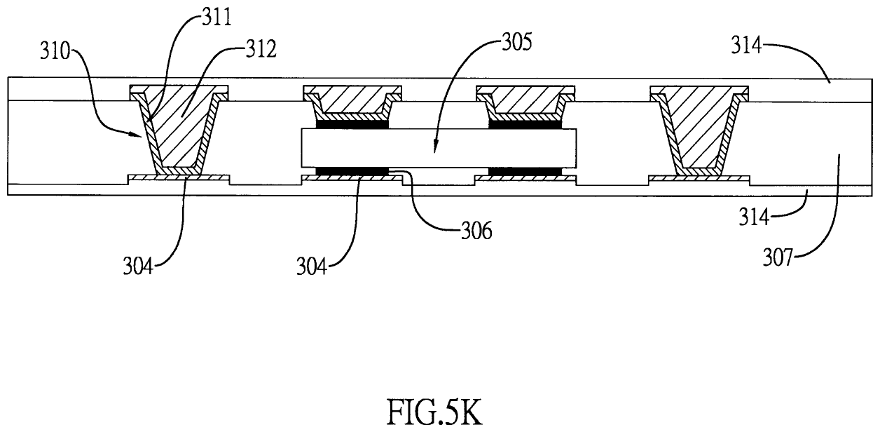

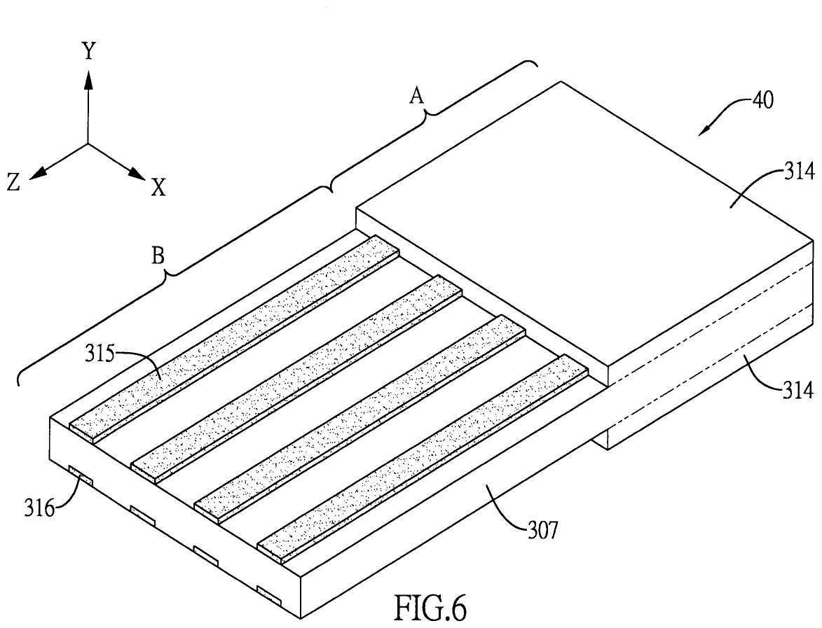

With reference to FIG. 5A, a carrier 300 has a metal seed layer 301 provided on at least one surface thereof. The metal seed layer 301 can be, but is not limited to, a copper foil. In the embodiment, the carrier 300 has two metal seed layers 301 respectively provided on two opposite surfaces, i.e. a top surface and a bottom surface of the carrier 30, for efficiently increasing production capacity.

With reference to FIG. 5B, photoresist layers 302 are respectively applied on the two metal seed layers 301. The two photoresist layers 302 are patterned to form multiple openings 303 to expose the metal seed layers 301.

With reference to FIGS. 5C and 5D, after lower circuit layers 304 are each formed on the surface of each metal seed layer 301 through the openings 303, the photoresist layers 302 are removed. As an example, the metal seed layer 301 may be the copper foil, and the lower circuit layers 304 in the openings 303 can be formed by electroplating.

With reference to FIG. 5E, a die 305 is attached on the top side of the carrier 300, wherein bottom pads 306 formed on a bottom of the die 305 are electrically connected to the respective lower circuit layers 304. A dielectric layer 307 is subsequently provided to cover the metal seed layer 301 on the top surface of the carrier 300, the lower circuit layers 304 and the die 305. With reference to FIG. 5F, on the bottom side of the carrier 300, another die 305 and another dielectric layer 307 are provided. The method for making the top side of the carrier board is used as an example and described hereinafter, and the bottom side of the carrier board 300 can be processed in the same way.

With reference to FIG. 5G, multiple vias 308 are formed through the dielectric layer 307. As an example, the laser drilling process is applied to form the vias 308. Each of the vias 308 can be a tapered hole. The positions of the multiple vias 308 correspond to the lower circuit layers 304 and top pads 309 formed on the top surface of the die 305 so that the lower circuit layers 304 and the top pads 309 are exposed from the vias 308.

With reference to FIG. 5H, an upper circuit layer 310 is formed in each via 308 of the dielectric layer 307. Each upper circuit layer 310 has a composite structure including a conductive bottom layer 311 and a conductive filler 312. The conductive bottom layer 311 is formed in an inner surface of the via 308, the top surface of the lower circuit layer 304, and the top surface of the dielectric layer 307. The conductive filler 312 is electrically combined with the conductive bottom layer 311. With reference to FIG. 5H, the upper circuit layer 310 has a cross section like a conductive via. The upper circuit layers 310, with their bottom surfaces, are electrically connected to the respective lower circuit layers 304 and the top pads 309 on the die 305. Each upper circuit layer 310 may protrude from the top surface of the dielectric layer 307. It is noted that the lower circuit layers 304 and the upper circuit layers 310 collectively form the redistribution layer (RDL). The layout patterns of the lower circuit layers 304 and the upper circuit layers 310 correspond to the layout patterns of the conductive traces 13, the conducting layers 221, 222 of the leads 20 in the main body 10 as discussed above.

With reference to FIG. 5I, the carrier 300 is removed from the metal seed layer 301, whereby a bottom surface of the metal seed layer 301 is exposed.

With reference to FIG. 5J, the metal seed layer 301 is then removed, for example by etching. In one embodiment, an over etching process is applied to remove the metal seed layer 301 as well as bottom portions of the lower circuit layers 304. After the over etching, the bottom surface of the dielectric layer 307 is not coplanar with the bottom surfaces of the lower circuit layers 304. Taking the bottom surface of the dielectric layer 307 as a reference plane, multiple recesses 313 can be deemed as being formed in the reference plane after the over etching process, and the lower circuit layers 304 are respectively provided in the recesses 313. Accordingly, a step portion is formed between the bottom surface of the dielectric layer 307 and the bottom surface of each lower circuit layer 304.

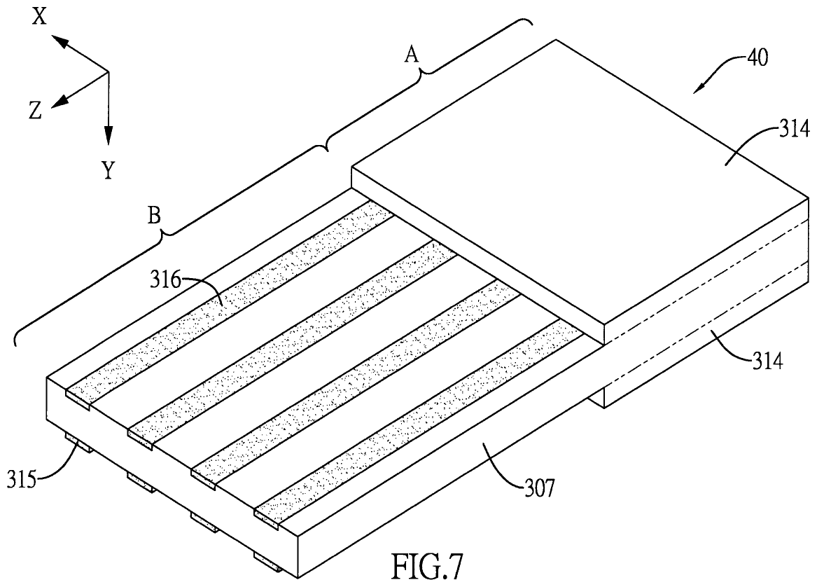

FIG. 5K is a cross sectional view illustrating a main body region A of a semi-finished product 40 as shown in FIG. 6. Protection layers 314 such as solder mask layers are provided on the top side and the bottom side of the dielectric layer 307 respectively in the main body region A. One of the protection layers 314 covers the top surface of the dielectric layer 307 and the top surfaces of the upper circuit layers 310. The other protection layer 314 covers the bottom surface of the dielectric layer 307 and the bottom surfaces of the lower circuit layers 310.

With regard to the upper circuit layers 310 and the lower circuit layers 304 that are uncovered by the protection layers 314 in a lead area B of the semi-finished product 40, as seen in FIG. 6, a first conducting layer 315 is formed on the top surfaces of the upper circuit layers 310 and a second conducting layer is formed on the bottom surface of the lower circuit layers 304 through a surface treatment. The surface treatment may include, but is not limited to, electroless tin (E′less Sn) plating process, electroless nickel immersion gold (ENIG) process, hot air solder leveling (HASL) process, organic solderability preservative (OSP) process, etc.

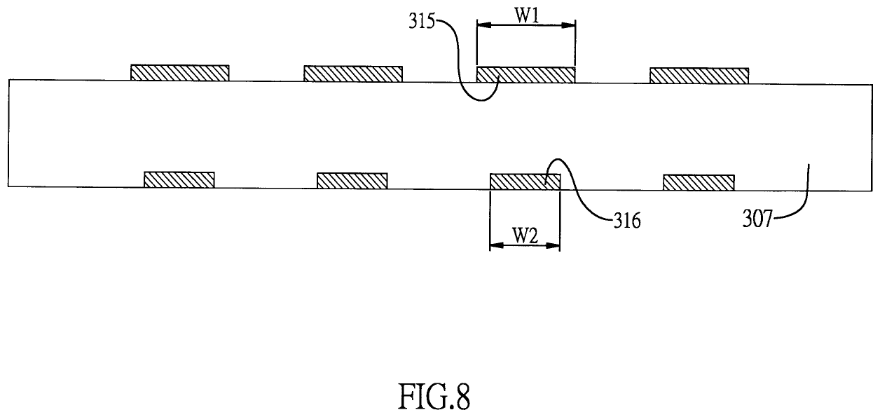

FIGS. 6 and 7 show the semi-finished product 40 which is composed of the main body region A and the lead area B. FIG. 8 is a cross sectional view of the lead area B shown in FIG. 6. The protection layers 314 are provided to cover the dielectric layer 307 in the main body region A as well as the upper circuit layers 310 and the lower circuit layers 304 formed in the main body region A. The dielectric layer 307 in the lead area B, the upper circuit layers 310 and the lower circuit layers 304 in the lead area B are exposed without being covered by the protection layers 314 for surface treatment. After the surface treatment, the first conducting layer 315 is formed on the top surfaces of each upper circuit layer 310 in the lead area B, and the second conducting layer 316 is formed on the bottom surface of each lower circuit layer 304 in the lead area B.

According to the embodiment shown in FIG. 8, each first conducting layer 315 has a first trace width W1 wider than a second trace width W2 of each second conducting layer 16. As shown in FIGS. 6 and 7, all the first conducting layers 315 are formed in a linear shape and parallel to each other, and all the second conducting layers 316 are also formed in a linear shape and parallel to each other. The first conducting layers 315 respectively correspond to the second conducting layers 316 in position. In other embodiments, the first trace width W1 of each first conducting layer 315 equals the second trace width W2 of each second conducting layer 316.

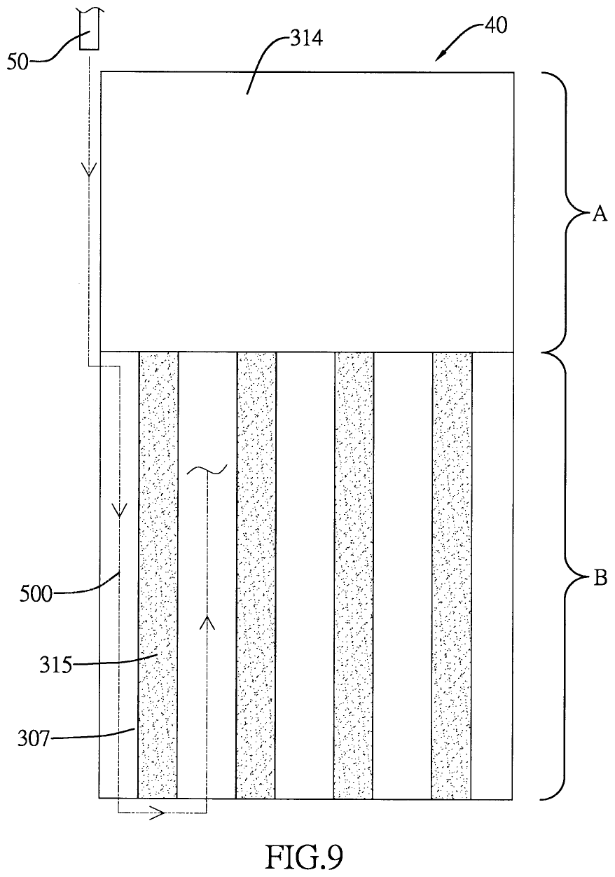

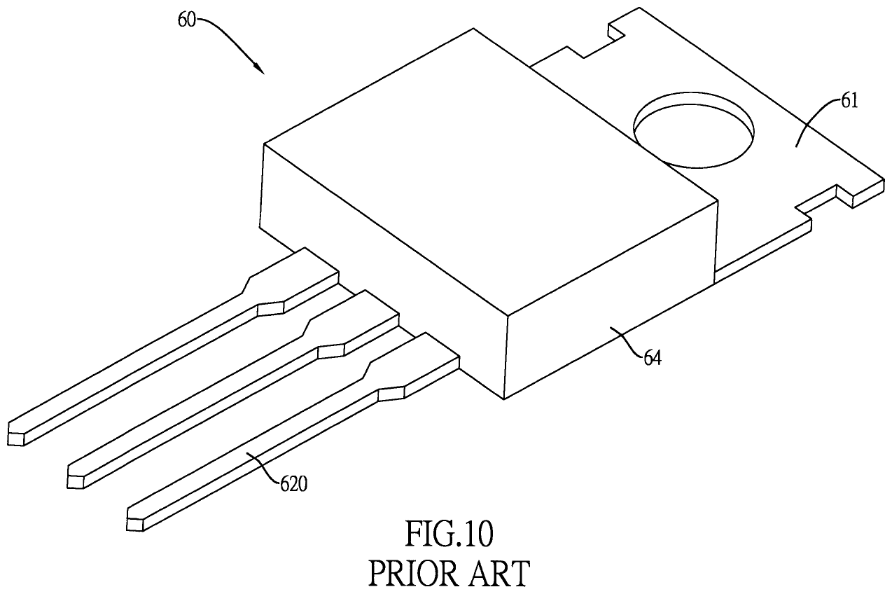

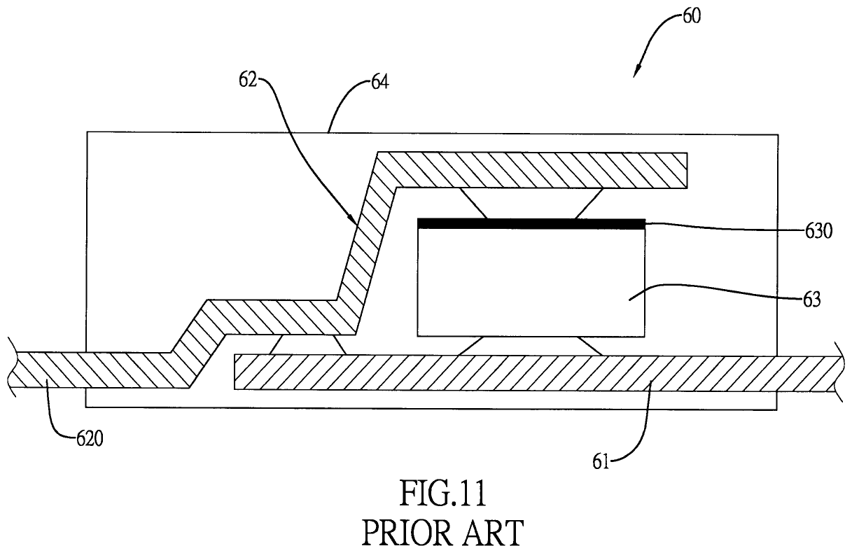

With reference to FIG. 9, in a package outline forming process, a cutting tool 50 such as a milling cutter may be applied to cut the semi-finished product 40 along the cutting path 500. After cutting the semi-finished product 40, the main body region A of FIG. 9 forms the main body 10 as shown in FIG. 1. The dielectric layer 307 and the protection layers 314 in the main body region A constitute the insulating body 11 as shown in FIGS. 1 and 4. Furthermore, the lead area B in FIG. 9 is cut to form multiple leads 20 as shown in FIG. 1. The dielectric layer 307 in the lead area B forms the lead carrier 21 as shown in FIG. 1, and the first conducting layer 315 and the second conducting layer 316 respectively act as the conducting layers 222, 221 shown in FIG. 1. Other package outline forming processes such as stamping or laser cutting can be applied to form the leads 20.

In another embodiment, for each of the leads 20, the cutting path 500 is kept from a distance from the first conducting layers 315 and the second conducting layers 316. That is, the cutting tool 50 will not cut side edges of the first conducting layers 315 and the second conducting layers 316, but keeps a distance from the side edges of them. Therefore, the first conducting layers 315 and the second conducting layers 316 are embedded in the lead carrier 21 and act as the conducting layers 222, 221 in FIG. 4.

A package according to the present invention can be manufactured through panel level packaging (PLP) technology, and the leads 20 of the package are formed without using a lead frame. In comparison to the conventional packages using lead frames, since the present invention does not use lead frames and the wire bonding process, the present invention is irrelevant to the thickness of the lead frames and the loop height of the bonding wires. Accordingly, the overall thickness of the package in accordance with the present invention can be reduced for minimizing product size and improving heat dissipation effect.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. A package with embedded traces comprising:
a main body comprising:
an insulating body; and
a die and multiple conductive traces mounted in the insulating body, wherein the die is electrically connected to the multiple conductive traces; and
multiple leads extending outward from the main body, and each of the multiple leads comprising:
a lead carrier integrally extending from the isolation body and having two opposite surfaces; and
two conducting layers formed on the two opposite surfaces of the lead carrier respectively and electrically connected to one of the multiple conductive traces so that the two conducting layers of each lead are electrically connected to the die, wherein at least one of the two conducting layers of each lead is embedded in the lead carrier.

2. The package as claimed in claim 1, wherein for each of the multiple leads:
two gaps are respectively formed between two side edges of the lead carrier and two side edges of the at least one of the two conducting layers which is embedded in the lead carrier; and
the other one of the two conducting layers has two side edges respectively aligning with the two side edges of the lead carrier.

3. The package as claimed in claim 1, wherein the two conducting layers of each lead are both embedded in the lead carrier.

4. The package as claimed in claim 3, wherein two gaps are respectively formed between two side edges of the lead carrier and two side edges of each conducting layer embedded in the lead carrier.

5. The package as claimed in claim 1, wherein the multiple leads extend outward from the same side of the main body.

6. The package as claimed in claim 1, wherein the two conducting layers of each lead are electrically connected to each other through a conductive via formed in the main body.

7. The package as claimed in claim 2, wherein the two conducting layers of each lead are electrically connected to each other through a conductive via formed in the main body.

8. The package as claimed in claim 3, wherein the two conducting layers of each lead are electrically connected to each other through a conductive via formed in the main body.

9. The package as claimed in claim 4, wherein the two conducting layers of each lead are electrically connected to each other through a conductive via formed in the main body.

10. The package as claimed in claim 5, wherein the two conducting layers of each lead are electrically connected to each other through a conductive via formed in the main body.
